(19) United States
(12) Patent Application Publication
(10) Pub. No.: US 2009/0185150 A1
(43) Pub. Date: Jul. 23, 2009

(54) IMMERSION EXPOSURE APPARATUS AND DEVICE MANUFACTURING METHOD

(75) Inventor: Tomoharu Hase, Kyoto-shi (JP)

Correspondence Address: Locke Lord Bissell & Liddell LLP;Attn: IP Docketing, Three World Financial Center, New York, NY, 10281-2101, US

(73) Assignee: CANON KABUSHIKI KAISHA, Tokyo (JP)

(21) Appl. No.: 12/356,645

(22) Filed: Jan. 21, 2009

(30) Foreign Application Priority Data
Jan. 22, 2008 (JP) 2008-011925

(51) Int. Cl. G03B 27/52; G03F 7/20

(52) U.S. Cl. 355/30; 430/325

(57) ABSTRACT

An immersion exposure apparatus which includes an original stage which moves with holding an original; a substrate stage which includes a liquid supporting plate which has a liquid repellent surface and is located around a substrate holding region which holds a substrate; and a projection optical system, and scan-exposes the substrate while a gap between the substrate and the projection optical system is filled with a liquid, the apparatus comprising a movable blind configured to move in a direction different from a scanning direction of the scanning exposure and limit an irradiated region of exposure light, and a controller configured to control the movement of the movable blind in synchronism with the scanning exposure so as to reduce an amount of the exposure light which the liquid supporting plate.

### BACKGROUND OF THE INVENTION

1. Field of the Invention

The present invention relates to an immersion exposure apparatus which scan-exposes a substrate by projecting the pattern of an original onto the substrate by a projection optical system while the gap between the substrate and the projection optical system is filled with a liquid, and a device manufacturing method.

2. Description of the Related Art

A semiconductor device and liquid crystal display device are manufactured by so-called photolithography which transfers a pattern formed on an original (also called a mask or reticle) onto a photosensitive substrate. An exposure apparatus used in photolithography includes an original stage which supports an original and a substrate stage which supports a substrate. The apparatus transfers a pattern formed on the original onto the substrate via a projection optical system while moving the original stage and the substrate stage step by step.

In recent years, to cope with a further increase in packing density along with miniaturization of device patterns, the projection optical system is required to attain a higher resolution. The use of a shorter exposure wavelength and a higher numerical aperture of the projection optical system is advantageous to increasing the resolution of the projection optical system. In view of this, the wavelength of exposure light used for the exposure apparatus is shortening, and the numerical aperture of the projection optical system is increasing. The current mainstream exposure wavelengths are a KrF excimer laser oscillation wavelength of 248 nm and an ArF excimer laser oscillation wavelength of 193 nm, which have already been put to practical use. The depth of focus (DOF) is an important factor in exposure as well as the resolution. The resolution R and the depth of focus δ are given by:

R=k1·λ/NA . . . (1)

δ=±k2·λ/NA² . . . (2)

where δ is the exposure wavelength, NA is the numerical aperture of the projection optical system, and k1 and k2 are process coefficients.

As can be understood from equations (1) and (2), as the exposure wavelength λ is shortened and the numerical aperture NA is increased in order to increase the resolution R, the depth of focus δ decreases.

As the depth of focus δ decreases, it becomes difficult to stably align the substrate surface with the image plane of the projection optical system. This makes it impossible to obtain a desired resolution. In addition, optical component materials usable for the exposure light that tends to have a shorter wavelength are limited. From this viewpoint, an immersion method is available as a method of practically shortening the wavelength of the exposure light having propagated through the projection optical system, and increasing the depth of focus at the same time. In the immersion method, an immersed region is formed by filling the gap between the substrate surface and the lower surface of the projection optical system with a liquid such as water or an organic solvent. Using the principle according to which the wavelength of the exposure light in the liquid is 1/n (n is the refractive index of the liquid and is typically about 1.2 to 1.6) that in the air, the resolution is improved and the depth of focus is increased (to about n times).

Japanese Patent Laid-Open No. 2005-19864, for example, discloses a method of filling the gap between the wafer surface (substrate surface) and the final surface of the projection optical system with a liquid using the immersion method.

This method aims to surely fill the gap between the substrate and the final surface of the projection optical system with a liquid in an exposure apparatus to which the immersion method is applied. The exposure apparatus includes a liquid supply nozzle located around the projection optical system in a first direction when viewed from the projection optical system. When the substrate stage moves the substrate in a second direction opposite to the first direction, a liquid is supplied onto the substrate surface through the liquid supply nozzle to form a liquid film on the surface. The liquid is continuously supplied onto the substrate surface through the liquid supply nozzle so that the liquid film continuously spreads along with the movement of the substrate. This makes it possible to surely fill the gap between the substrate and the final surface of the projection optical system with the liquid.

The region filled with the liquid (to be referred to as the immersed region hereinafter) must be wider than the projection region of the exposure light on the substrate or substrate stage. When the edge region on the photosensitive substrate is exposed in the exposure apparatus to which the immersion method is applied, a part of the immersed region falls outside the photosensitive substrate and is formed on the substrate stage. As a part of the immersed region is formed on the substrate stage, it becomes difficult to satisfactorily hold the liquid in the immersed region due to the presence of steps and gaps. In addition, the liquid is likely to remain on the substrate stage. Along with evaporation of the residual liquid, for example, the environment (temperature and humidity) under which the photosensitive substrate is set may vary, the substrate stage may thermally deform, or the environments in the optical paths of various measurement light beams which measure, for example, the position information of the photosensitive substrate may vary, resulting in a decrease in the exposure accuracy. After the residual liquid evaporates, a watermark (water trace) remains on the substrate stage, which may contaminate, for example, the photosensitive substrate or liquid or generate errors of various kinds of measurement.

As a means for solving these problems, Japanese Patent Laid-Open No. 2005-191557, for example, discloses an immersion exposure apparatus which prevents the liquid from remaining on the substrate stage.

This immersion exposure apparatus includes a substrate stage which holds a photosensitive substrate. A liquid supporting plate (for example, a plane-parallel plate) is arranged on the substrate stage to have its surface nearly flush with the substrate in order to hold the liquid in the immersed region. The liquid supporting plate is coated with a liquid repellent coating to be able to satisfactorily hold the immersed region even when the edge region is exposed. A coating made of a fluorine compound typified by tetrafluoroethylene is disclosed as the repellent coating.

The field is often stopped down to define the illuminated region on the original. Japanese Patent Laid-Open No. 2005-93693, for example, discloses an exposure apparatus including a masking blade having a light-shielding plate which can move in the scanning direction of scanning exposure.

The exposure apparatuses to which the immersion method is applied, as disclosed in Japanese Patent Laid-Open Nos. 2005-19864 and 2005-191557 mentioned above, can satisfactorily hold the immersed region when the edge region on the photosensitive substrate is exposed. However, when these exposure apparatuses expose the photosensitive substrate using an original on which a plurality of chip patterns as shown in FIG. 5A (in this case, 2×3 chip patterns) are drawn, shot regions in the edge portion often fall outside the photosensitive substrate, as shown in FIG. 3A.

In this case, the exposure light is projected onto the substrate stage outside the photosensitive substrate upon exposing the shot regions in the edge portion. The exposure apparatuses using the immersion method irradiate the surface of the liquid supporting plate coated with a coating made of a fluorine compound with the exposure light. The coating made of a fluorine compound is known to significantly deteriorate upon being irradiated with laser light having a short wavelength for use in exposure. Because of the deterioration of the coating made of a fluorine compound upon irradiation with laser light, not only its repellency deteriorates but also it contaminates, for example, the photosensitive substrate or liquid upon its separation or the like. Therefore, shots B in the edge portion shown in FIG. 3A cannot be exposed. In other words, the conventional exposure apparatuses can ensure a shot layout including both shots A and shots B shown in FIG. 3A, but the exposure apparatuses using the immersion method must inevitably use a shot layout as shown in FIG. 3B, so the number of shots decreases drastically.

The technique disclosed in Japanese Patent Laid-Open No. 2005-93693 is not specially proposed assuming an immersion exposure apparatus, and merely shows a detailed arrangement which stops down the field to define the illuminated region on the original. This arrangement therefore does not solve the above-described problems.

### SUMMARY OF THE INVENTION

It is an object of the present invention to ensure a larger number of shots per substrate while suppressing deterioration of, for example, a liquid supporting plate in an immersion exposure apparatus.

According to the first aspect of the invention, there is provided an immersion exposure apparatus which includes an original stage which moves with holding an original, a substrate stage which includes a liquid supporting plate which has a liquid repellent surface and is located around a substrate holding region which holds a substrate, and a projection optical system, and scan-exposes the substrate while a gap between the substrate and the projection optical system is filled with a liquid, the apparatus comprising a movable blind configured to move in a direction different from a scanning direction of the scanning exposure and limit an irradiated region of exposure light, and a controller configured to control the movement of the movable blind in synchronism with the scanning exposure so as to reduce an amount of the exposure light which the liquid supporting plate.

According to the second aspect of the present invention, there is provided a device manufacturing method comprising the steps of exposing a substrate using an immersion exposure apparatus, and developing the substrate, wherein the immersion exposure apparatus includes an original stage which moves with holding an original, a substrate stage which includes a liquid supporting plate which has a liquid repellent surface and is located around a substrate holding region which holds a substrate; and a projection optical system, and scan-exposes the substrate while a gap between the substrate and the projection optical system is filled with a liquid, the apparatus comprising a movable blind configured to move in a direction different from a scanning direction of the scanning exposure and limit an irradiated region of exposure light, and a controller configured to control the movement of the movable blind in synchronism with the scanning exposure so as to reduce an amount of the exposure light which the liquid supporting plate.

Further features of the present invention will become apparent from the following description of exemplary embodiments with reference to the attached drawings.

### BRIEF DESCRIPTION OF THE DRAWINGS

FIG. 1 is a schematic view showing an exposure apparatus which can suitably practice the present invention;

FIG. 2 is a plan view showing a wafer stage in the exposure apparatus according to the present invention;

FIGS. 3A and 3B are views for explaining the shot layouts of the conventional exposure apparatus and conventional immersion exposure apparatus;

FIG. 4 is a view for explaining a movable blind according to the present invention;

FIGS. 5A to 5E are views for explaining a method of driving the movable blind during exposure in the exposure apparatus according to the present invention; and

FIGS. 6A and 6B are views for explaining discarded shots when the wafer is partially shielded against light by the exposure apparatus according to the present invention;

### DESCRIPTION OF THE EMBODIMENT

An embodiment of the present invention will be described in detail below with reference to the accompanying drawings.

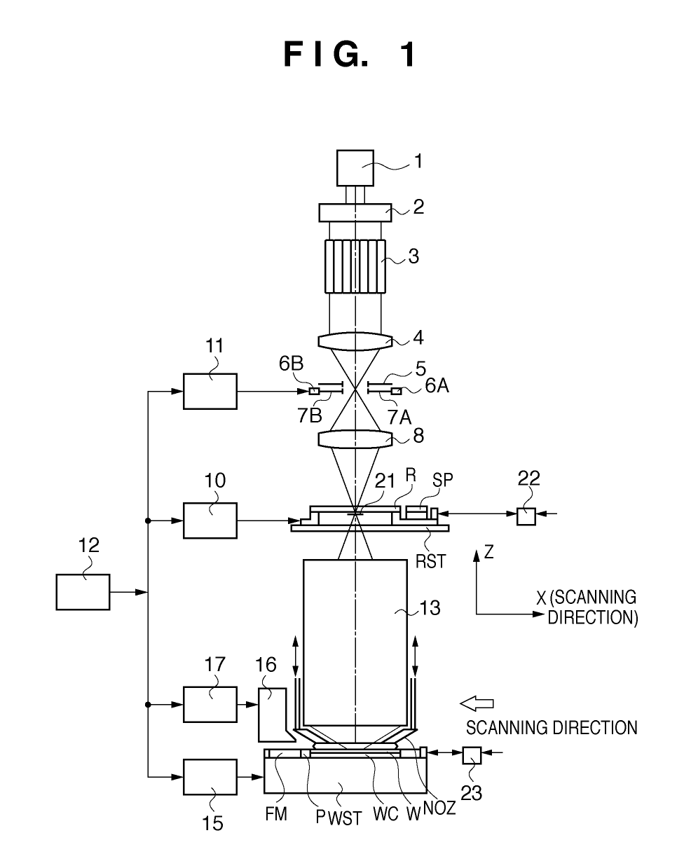

FIG. 1 is a schematic view showing an exposure apparatus which can suitably practice the present invention.

Referring to FIG. 1, illumination light from a light source 1 illuminates a rectangular slit shaped illuminated region 21 on an original R with a uniform illuminance upon propagating through an illumination optical system including an illumination light shaping optical system 2 to a relay lens 8. The circuit pattern image on the original R in the slit shaped illuminated region 21 is transferred onto a wafer (substrate) W via a projection optical system 13.

The light source 1 can be an excimer laser light source such as an F₂ excimer laser, ArF excimer laser, or KrF excimer laser. Alternatively, the light source 1 can be a metal vapor laser light source, a pulsed light source such as a harmonic generator of a YAG laser, or a continuous light source such as an arrangement which combines a mercury lamp and an elliptic reflecting mirror.

If the light source 1 is a pulsed light source, exposure is switched on or off by controlling power supplied from its power supply. If the light source 1 is a continuous light source, exposure is switched on or off by a shutter in the illumination light shaping optical system 2. In this embodiment, a movable blind (variable field stop) 7 including movable blinds 7A, 7B, 7C, and 7D (to be described later) is provided, so exposure may be switched on or off by opening or closing the movable blind 7.

Referring to FIG. 1, illumination light from the light source 1 is set to have a predetermined diameter by the illumination light shaping optical system 2, and reaches a fly-eye lens 3. A large number of secondary sources are formed on the exit surface of the fly-eye lens 3. Illumination light emanating from these secondary sources is converged by a condenser lens 4 and reaches the movable blind 7 via a fixed field stop 5.

Although the field stop 5 is located on the side of the condenser lens 4 with respect to the movable blind 7 in FIG. 1, conversely, it may be located on the side of the relay lens 8 with respect to the movable blind 7. The field stop 5 has a rectangular slit shaped aperture formed in it. A light beam having passed through the field stop 5 turns into that having a rectangular slit shaped section, and enters the relay lens 8. The slit longitudinal direction is a direction perpendicular to the paper surface, that is, a direction perpendicular to both the X- and Z-axis directions in FIG. 1. The moving direction of the original R (the scanning direction of the original R with respect to the slit shaped illuminated region 21 (to be also simply referred to as the scanning direction hereinafter)) is the direction indicated by an arrow (X-axis direction) in FIG. 1.

The relay lens 8 sets the movable blind 7 which limits the irradiated region of the exposure light to be conjugate to the pattern forming surface of the original R.

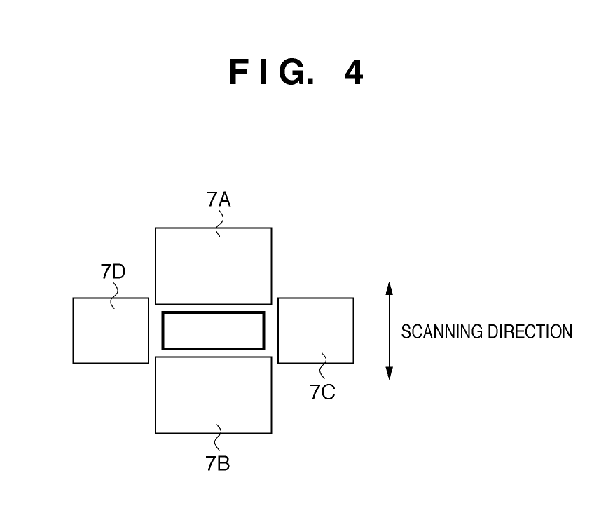

The movable blind 7 is inserted between the light source 1 and the original R along the irradiation path of the exposure light. The movable blind 7 is arranged, as shown in FIG. 4, and includes two rectangular movable blinds (light-shielding plates) 7A and 7B which define the dimension in the scanning direction (the X-axis direction in FIG. 1), and two rectangular movable blinds 7C and 7D which define the dimension in the non-scanning direction perpendicular to the scanning direction. The movable blinds 7A and 7B which define the dimension in the scanning direction can be independently driven in the scanning direction by movable blind driving portions 6A and 6B, respectively. The two movable blinds 7C and 7D which define the dimension in the non-scanning direction can be independently driven by movable blind driving portions (not shown) as well.

In this embodiment, the illumination light irradiates only the exposure region set by the movable blind 7 in the slit shape illuminated region 21 on the original R, which is set by the fixed field stop 5.

The relay lens 8 is a bilateral telecentric optical system whose telecentricity is maintained in the slit shaped illuminated region 21 on the original R. The original R is held by an original stage RST. The position of the original stage RST is detected by an interferometer 22, and the original stage RST is driven by an original stage driving portion 10. A reference plate SP on which a reference mark to calibrate the exposure apparatus is formed is arranged on the original stage RST.

The circuit pattern image on the original R defined by the movable blind 7 in the slit shaped illuminated region 21 is projected and transferred by exposure onto the wafer W via the projection optical system 13.

On a two-dimensional plane perpendicular to the optical axis of the projection optical system 13, the scanning direction of the original R with respect to the slit shaped illuminated region 21 is defined as the X-axis direction (+X direction or −X direction), and a direction parallel to the optical axis of the projection optical system 13 is defined as the Z-axis direction.

In this embodiment, a main controller 12 controls the overall operation of the exposure apparatus. The original stage driving portion 10 moves the original stage RST under the control of the main controller 12, thereby scanning the original R in the scanning direction (+X direction or -X direction). A movable blind controller 11 controls the movable blind driving portions 6A and 6B of the movable blinds 7A and 7B for the scanning direction, and the driving portions of the movable blinds 7C and 7D for the non-scanning direction in accordance with a control command received from the main controller 12. With this operation, the movable blinds 7A, 7B, 7C, and 7D move under the control of the movable blind controller 11.

A wafer W is conveyed by a wafer conveyance device (not shown) and chucked by vacuum suction by a wafer chuck WC arranged on a wafer stage (substrate stage) WST, thereby being held in the wafer holding region (substrate holding region). The wafer stage WST includes, for example, an X-Y stage which aligns the wafer W on a plane perpendicular to the optical axis of the projection optical system 13 and scans it in the X-axis direction, and a Z stage which aligns the wafer W in the Z-axis direction. The position of the wafer stage WST is detected by an interferometer 23.

The immersion exposure apparatus according to this embodiment can detect not only the position of the wafer stage WST in the X-axis direction, but also its position in the Y-axis direction perpendicular to both the X- and Z-axes, and its position in the rotation directions about the X- and Y-axes. A reference mark FM for use in apparatus calibration or wafer alignment is formed on the wafer stage WST. A liquid repellent liquid supporting plate P set nearly flush with the surface of the wafer W is arranged around the wafer W, and is held while being chucked by vacuum suction by the wafer stage WST.

A liquid supply-and-recovery portion NOZ which supplies and recovers a liquid to immerse the image plane of the projection optical system 13 (to fill the gap between the wafer W and the final surface of the projection optical system 13, which opposes the wafer W) is arranged on the side of the image plane of the projection optical system 13 above the wafer W. The liquid supply-and-recovery portion NOZ is connected to a supply portion including a liquid supply pipe, pump, temperature controller, and filter, and a recovery portion including a liquid recovery pipe, pump, and gas-liquid separator (neither are shown). The main controller 12 controls liquid supply and recovery of the supply portion and recovery portion.

An off-axis alignment sensor 16 is arranged above the wafer W. The alignment sensor 16 detects an alignment mark on the wafer, and sends the detection result to the main controller 12 under the control of a controller 17. The main controller 12 controls the alignment operation and scanning operation of the wafer stage WST via a wafer stage driving portion 15.

In projecting the pattern image on the original R onto each shot region on the wafer W via the projection optical system 13 by the scanning exposure scheme, the original R is scanned in the X-axis direction with respect to the slit shaped illuminated region 21 set by the field stop 5 shown in FIG. 1 at a velocity VR. Letting β be the projection magnification of the projection optical system 13, the wafer W is scanned in the X-axis direction in synchronism with the scanning of the original R at a velocity VW (=β·VR). With this operation, the circuit pattern image on the original R is transferred onto each shot region on the wafer W step by step.

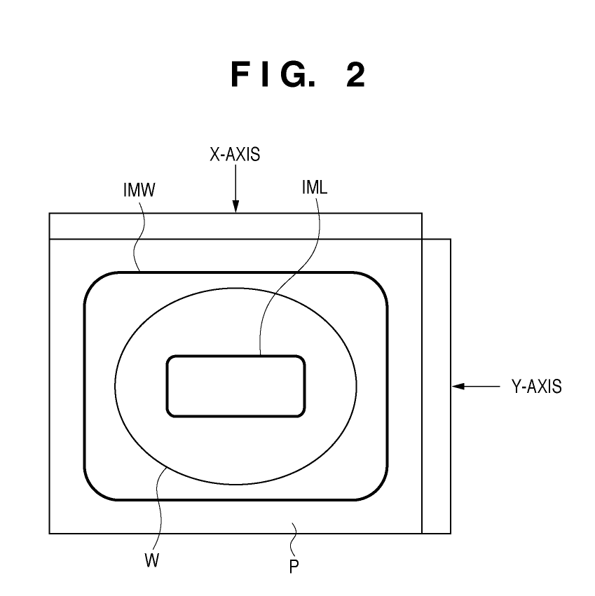

FIG. 2 is a plan view showing the wafer stage WST. FIG. 2 conceptually shows a portion in contact with an immersed region IML in wafer exposure as a liquid contacting region IMW. To satisfactorily hold the liquid in the liquid contacting region IMW, the liquid supporting plate P has an area larger than that of the liquid contacting region IMW, and the surface of the liquid supporting plate P is coated with a coating made of a fluorine compound such as tetrafluoroethylene (not shown).

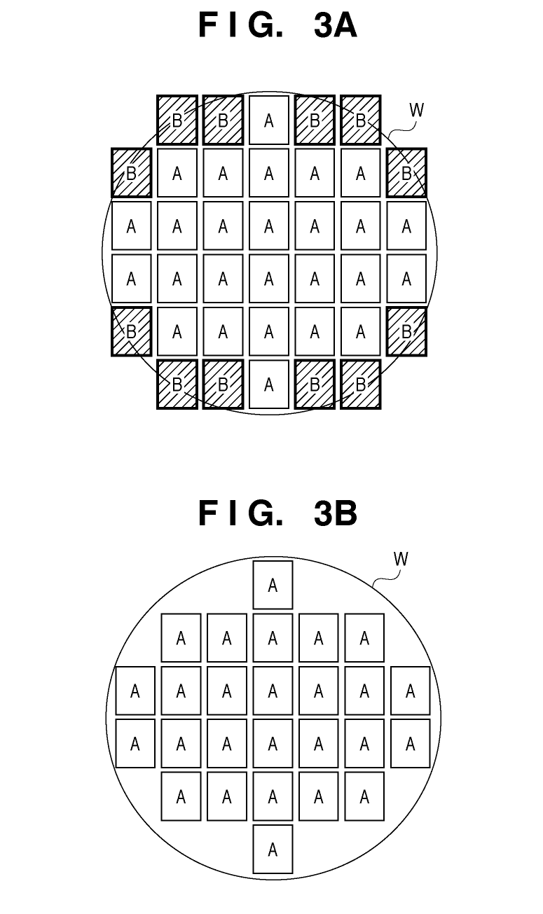

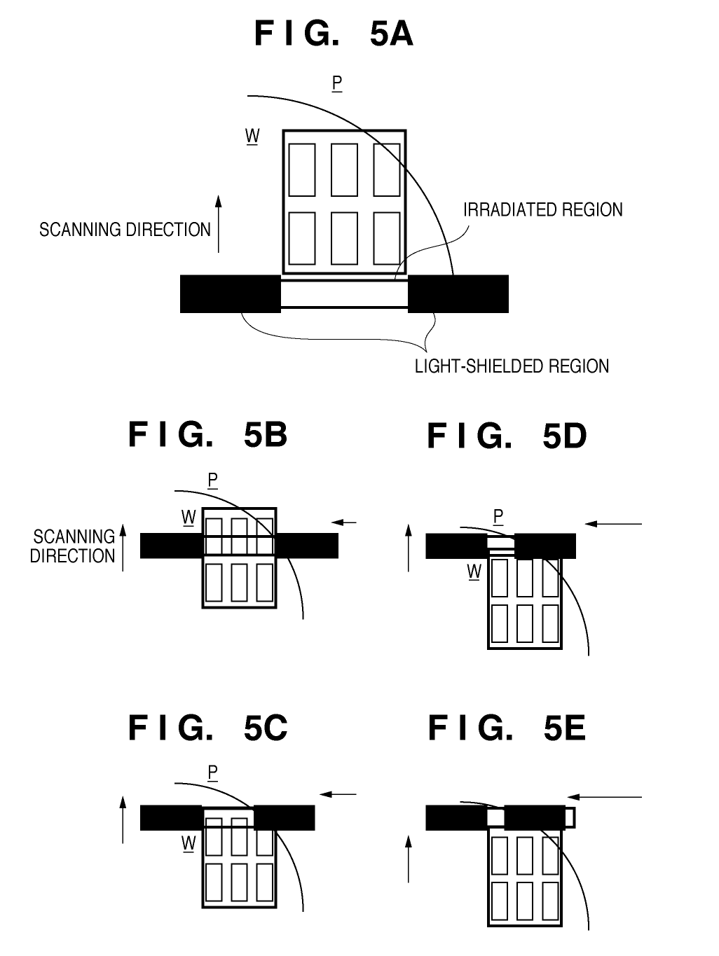

The movable blinds 7A and 7B shown in FIG. 4 are used to define the dimension in the scanning direction, as described above, and are driven in synchronism with the original and wafer in order to prevent the projection light from irradiating adjacent shots at the start and end of exposure. The movable blinds 7C and 7D can move in a direction perpendicular to the scanning direction and are used to define the dimension in this direction. The movable blinds 7C and 7D are never driven during scanning exposure when shots at the central portion of the wafer, such as shots A shown in FIG. 3A, are exposed. In other words, the movable blinds 7C and 7D are stopped under the control of the movable blind controller 11 during scanning exposure in a region other than that including the edge portion. In contrast, when shots in the edge region, such as shots B shown in FIG. 3A, are exposed, the exposure light needs to be prevented from irradiating even the liquid supporting plate. For this reason, the movable blind controller 11 controls the movement of the movable blind 7C or 7D so that one end of the irradiated region traces the shape of the wafer edge portion, as shown in FIGS. 5A to 5E, during scanning exposure.

Driving control of the movable blinds 7C and 7D by the movable blind controller 11 in exposing shot regions including the wafer edge portion will be explained with reference to FIGS. 5A to 5E. During scanning exposure in the states shown in FIGS. 5A and 5B, that is, until the exposure light reaches the wafer edge portion, the movable blinds are not driven. In contrast, during scanning exposure in the states shown in FIGS. 5B to 5D, that is, during scanning exposure in a region including the wafer edge portion, the movable blinds are driven to move along the shape of the wafer edge portion so as to prevent the exposure light from irradiating the liquid supporting plate outside the wafer edge portion. In this way, the amount of exposure light which impinges on the liquid supporting plate is reduced. More specifically, the movable blind controller 11 moves a movable blind on the side of the wafer edge portion in a direction perpendicular to the scanning direction so that one end of the irradiated region traces the wafer edge portion. Note that the irradiated region means herein the irradiated region of the exposure light which irradiates the wafer surface. The movable blind controller 11 moves the movable blinds so that the irradiated region traces the shape of the wafer edge portion.

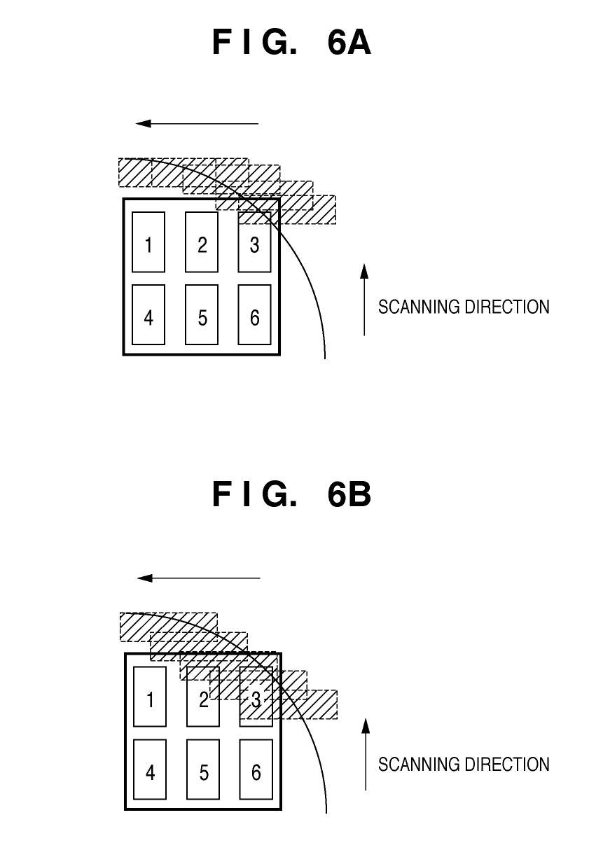

The use of an original on which 2×3 patterns are drawn as shown in FIG. 6A involves discarded shots because several patterns drawn at positions 1, 2, 3, 5, and 6 shown in FIG. 6A are shielded against light (the light-shielded region changes depending on the position on the wafer). Nevertheless, several exposure shots can be ensured in a region which cannot be exposed in the conventional exposure apparatuses. The movable blinds 7C and 7D may be driven not only along the shape of the wafer but also along the shape of the liquid supporting plate.

To drive the movable blinds along the shape of the wafer or liquid supporting plate, as described above, high-accuracy driving control which achieves high-acceleration/deceleration driving is necessary. To facilitate the driving control, as shown in FIG. 6B, discarded shots or driving patterns may be preset and the movable blinds may be driven at a constant velocity. In this case, the number of discarded shots increases as compared with a case in which the movable blinds are driven along the shape of the wafer or liquid supporting plate, but there is a merit of obtaining a larger number of shots than in the conventional exposure apparatuses, thus facilitating the driving control.

A device manufacturing method according to the preferred embodiments of the present invention is suitable for the manufacture of devices (e.g., a semiconductor device and liquid crystal device). This method can include a step of exposing a substrate coated with a photoresist to light by using the above exposure apparatus, and a step of developing the substrate exposed in the exposing step. In addition to the above steps, the device manufacturing method can include other known steps (e.g., oxidation, film forming, evaporation, doping, planarization, etching, resist removing, dicing, bonding, and packaging steps).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-011925, filed Jan. 22, 2008, which is hereby incorporated by reference herein in its entirety.

What is claimed is:

1. An immersion exposure apparatus which includes an original stage which moves with holding an original; a substrate stage which includes a liquid supporting plate which has a liquid repellent surface and is located around a substrate holding region which holds a substrate; and a projection optical system, and scan-exposes the substrate while a gap between the substrate and the projection optical system is filled with a liquid, the apparatus comprising:
a movable blind configured to move in a direction different from a scanning direction of the scanning exposure and limit an irradiated region of exposure light; and
a controller configured to control the movement of the movable blind in synchronism with the scanning exposure so as to reduce an amount of the exposure light which the liquid supporting plate.

2. The apparatus according to claim 1, further comprising a movable blind driving portion configured to move the movable blind in a direction perpendicular to the scanning direction,
wherein the controller is configured to cause the driving portion to drive the movable blind in a direction perpendicular to the scanning direction such that an amount of the exposure light which impinges on the liquid supporting plate is reduced in scanning exposure in a region including an edge portion of the substrate.

3. The apparatus according to claim 2, wherein the controller is configured to stop the driving of the movable blind by the driving portion during scanning exposure in a region other than the region including the edge portion of the substrate.

4. The apparatus according to claim 2, wherein
the movable blind defines a dimension in the scanning direction in the irradiated region, and
the controller is configured to cause the driving portion to drive the movable blind in a direction perpendicular to the scanning direction so that one end of the irradiated region traces the edge portion in scanning exposure in the region including the edge portion of the substrate.

5. The apparatus according to claim 2, wherein the controller is configured to cause the driving portion to move the movable blind at a constant velocity in scanning exposure in the region including the edge portion of the substrate.

6. The apparatus according to claim 1, wherein the movable blind is located between the original and a light source to irradiate the original with light.

7. The apparatus according to claim 1, wherein the movable blind includes two rectangular light-shielding plates configured to define a dimension in the scanning direction, and two light-shielding plates configured to define a dimension in a direction perpendicular to the scanning direction.

8. The apparatus according to claim 7, further comprising driving portions configured to move, in a direction perpendicular to the scanning direction, the two rectangular light-shielding plates configured to define a dimension in a direction perpendicular to the scanning direction,
wherein the two rectangular light-shielding plates are individually driven by the driving portions in a direction perpendicular to the scanning direction.

9. The apparatus according to claim 7, further comprising driving portions configured to move, in the scanning direction, the two rectangular light-shielding plates configured to define a dimension in the scanning direction,
wherein the two rectangular light-shielding plates are individually driven by the driving portions in the scanning direction.

10. A device manufacturing method comprising the steps of:
exposing a substrate using an immersion exposure apparatus; and
developing the substrate,
wherein the immersion exposure apparatus includes an original stage which moves with holding an original; a substrate stage which includes a liquid supporting plate which has a liquid repellent surface and is located around a substrate holding region which holds a substrate; and a projection optical system, and scan-exposes the substrate while a gap between the substrate and the projection optical system is filled with a liquid, the apparatus comprising:
a movable blind configured to move in a direction different from a scanning direction of the scanning exposure and limit an irradiated region of exposure light; and
a controller configured to control the movement of the movable blind in synchronism with the scanning exposure so as to reduce an amount of the exposure light which the liquid supporting plate.
